(19) United States
(12) Patent Application Publication
(10) Pub. No.: US 2007/0194974 A1
(43) Pub. Date: Aug. 23, 2007

(54) Structure and method for reducing the current consumption of a capacitive load

(75) Inventor: Chun-Sheng Lin, Taipei City (TW)

Correspondence Address: BIRCH STEWART KOLASCH & BIRCH, PO BOX 747, FALLS CHURCH, VA, 22040-0747, US

(73) Assignee: Sitronix Technology Corp.

(21) Appl. No.: 11/357,068

(22) Filed: Feb. 21, 2006

(51) Int. Cl. H03M 1/12

(52) U.S. Cl. 341/172

(57) ABSTRACT

The present invention discloses a structure and method for reducing the current consumption of a capacitive load, wherein a storage capacitor is installed between a capacitive load and the output side of a drive element; a switch is used to switch the connection between the storage capacitor and the capacitive load and the connection between the output side and the capacitive load; when the output side is to undertake a signal transition, the switch interconnects the storage capacitor and the capacitive load to equalize those two capacitors; after the equalization is completed, the switch interconnects the output side and the capacitive load to charge the capacitive load; thus, the load capacitor of the capacitive load can be charged or discharged at an initial voltage level.

### FIELD OF THE INVENTION

The present invention relates to a load capacitor, which is charged or discharged with an initial voltage level having existed therein so that the current consumed by the capacitive load can be reduced.

### BACKGROUND OF THE INVENTION

With the tendency of integrating 3C—computer, communication, and consumer electronic products—into a unitary product, a single system chip will possess more and more functions. In the past, the function of a mobile phone is very simple, and now, a mobile phone has to possess diversified functions, such as the functions of a digital camera, an MP3 player and a game machine, so as to obtain the attention of the consumers. However, persistently increasing functions brings about the problem of high current consumption, and design engineers confront a challenge to achieve lower power consumption, longer battery life and more functions within a single chip. Therefore, engineers usually endeavor to reduce the power consumption of chips with various advanced designs.

At present, the integration level of an IC grows higher and higher, and the power management has become a key factor of IC design, and an inappropriate design of IC power management is apt to cause the failure of an IC design. It is also a great challenge to make chips with both high performance and low power consumption. The power consumption of IC may be divided into dynamic power consumption and static power consumption. The dynamic power consumption essentially results from the switching actions of elements and the charging/discharging actions of load capacitors. The static power consumption essentially results from the leakage current. In the non-conduction state of the transistors, the circuit has weak current due to the manufacturing process, which also causes power consumption.

The dynamic power consumption primarily occurs in the stage that the circuit is operating. As shown in Equation 1, the dynamic power consumption is the product of load capacitance C_{L}, supply voltage V_{DD} squared and frequency f. As all the gates do not switch simultaneously, a factor α, which is the average value of the switching activities of transistors and expressed by percentage, needs to be added into Equation 1.
P_{dynamic}=αC_{L}V_{DD}²f (1)

From Equation 1, it is known that reducing dynamic power consumption can be achieved via reducing frequency, supply voltage, or load capacitance. As an advanced IC design usually raises frequency to obtain better performance, the available method to reduce dynamic power consumption is to reduce supply voltage or load capacitance:
(1) Reducing supply voltage: as the dynamic power consumption is proportional to the square of supply voltage, reducing supply voltage can obtain a better effect. Since the IC industry began the CMOS process in 1980s, engineers can use advanced fabrication technologies to reduce dynamic power consumption. However, the supply voltage has approached the threshold voltage after the IC industry entered into the deep submicron process, and the further reduction of supply voltage can't obtain effects as satisfactory as before because of the process shrink. Another available method is to provide different supply voltages for different operations separately according to the voltage requirements thereof, and a lower voltage is supplied to the circuit operating in a lower speed.
(2) Reducing load capacitance: reducing the overall load capacitance is another approach to manage dynamic power consumption. As the clock is constantly switched, the load capacitance is relatively too high. Generally, the power consumed by the clock network reaches as high as 50% of the total power consumption. Therefore, the dynamic power consumption can be reduced via temporarily closing the unnecessary clock circuits; for example, a clock-gating approach can prevent a register from being constantly triggered by clock signals and can effectively minimize the total capacitance; thus, dynamic power consumption can be reduced thereby.

Please refer to FIG. 1, which is a diagram schematically showing a capacitive load, which is exemplified by the drive circuit of an LCD panel. The load structure of the LCD panel comprises a drive element 10 (such as an LCD driver IC), which utilizes two transistors PM and NM to control voltage signals (a high voltage level V_{DD} and a low voltage level V_{SS}) in order to control an output side V_{OUT} to output a signal to a load capacitor C_{L} (such as all the storage capacitors and parasitic capacitors of the same row of pixels on the panel) of a capacitive load 20 (such as the LCD panel). Refer to FIG. 2, which is a diagram showing the voltage signal of the output side V_{OUT}. When the capacitive load 20 is driven to operate, the load capacitor C_{L} will be completely charged (to the high voltage level V_{DD}) or completely discharged (to the low voltage level V_{SS}).

At present, the current consumed by the drive element 10 is progressively decreasing, and current is generally consumed by the capacitive load 20. If the current consumed by load can be reduced with supply voltage maintaining the same and without the penalty of the performance of the capacitive load 20, the total current consumption can be further decreased.

### SUMMARY OF THE INVENTION

The primary objective of the present invention is to reduce the total current consumption of products but still maintain supply voltage and load capacitance, i.e. to achieve higher power efficiency without the penalty of product performance.

The present invention proposes a method for reducing the current consumption of a capacitive load, wherein a storage capacitor is installed to the output side of a drive element, and a switch controls the storage capacitor; when the output side is to undertake a voltage signal transition, the output is closed firstly, and then, the storage capacitor and a load capacitor of the capacitive load are equalized; after the equalization is completed, the equalization process is turned off; owing to the equalization, the load capacitor of the capacitive load has reached a certain potential level beforehand, such as half of the voltage level.

After the equalization is turned off, the output side resumes sending voltage signals to the load capacitor. Duo to the storage capacitor and the load capacitor have been equalized earlier, so the output side can be charged or discharged under the condition of the load capacitor has been at an initial voltage level. Therefore, the output side needn't charge or discharge to the total range of the voltage level and pushing the load capacitor to the full voltage level does not need too much current. Thus, a portion of drive current can be saved, the current consumed by loads can be reduced, and the objective of saving power can be achieved.

### BRIEF DESCRIPTION OF THE DRAWINGS

FIG. 1 is a diagram schematically showing a conventional capacitive load.

FIG. 2 is a diagram schematically showing the signal of the output side of FIG. 1.

FIG. 3 is a diagram schematically showing the capacitive load according to the present invention.

FIG. 4 is a diagram schematically showing the signals of the nodes in the present invention when the capacitance of the storage capacitor is equal to the capacitance of the load capacitor.

FIG. 5 is a diagram schematically showing the signals of the nodes in the present invention when the ratio of the capacitance of the storage capacitor to the capacitance of the load capacitor is ½.

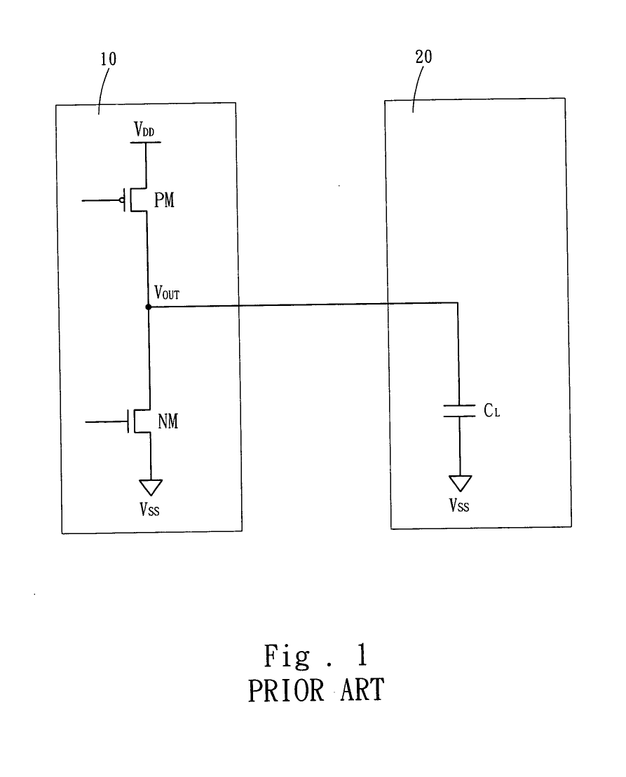

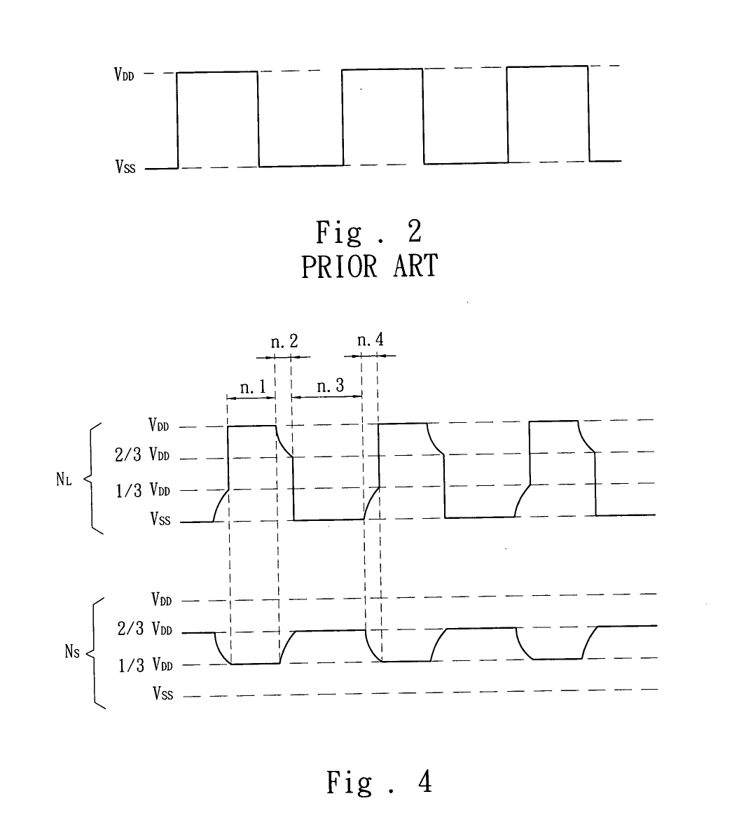

### DETAILED DESCRIPTION OF THE PREFERRED EMBODIMENTS

The technical contents of the present invention are to be described below in detail in cooperation with drawings.

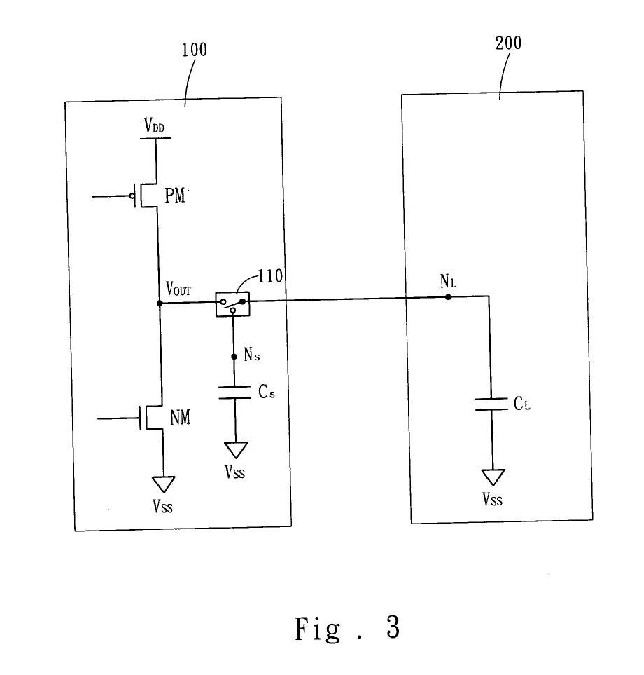

Please refer to FIG. 3, which is a diagram schematically showing a capacitive load according to one embodiment of the present invention. The driving process of an LCD panel is used to demonstrate the embodiment. The load structure of the panel comprises a drive element 100 (such as an LCD driver IC), which utilizes two transistors PM and NM to control voltage signals (a high voltage level V_{DD} and a low voltage level V_{SS}) in order to control an output side V_{OUT} to output a signal to a load capacitors C_{L} (such as all the storage capacitors and parasitic capacitors of the same row of pixels on the panel) of a capacitive load 200 (such as the LCD panel). A storage capacitor C_{S} is installed between the output side V_{OUT} and the capacitive load 200. A switch 110 is used to switch the connection between the storage capacitor C_{S} and the capacitive load 200 and the connection between the output side V_{OUT} and the capacitive load 200.

After the load capacitor C_{L} has been charged for the first time, and when the output side V_{OUT} is to undertake a signal transition to enable the load capacitor C_{L} to discharge, the switch 110 connects the load capacitor C_{L} and the storage capacitor C_{S} to enable the equalization of them firstly, and at this moment, the load capacitor C_{L} at the high voltage level V_{DD} charges the storage capacitor C_{S}. After the equalization is completed, the switch 110 switches to connect the output side V_{OUT} and the capacitive load 200 to enable the load capacitor C_{L} to discharge to the low voltage level V_{SS}.

When the load capacitor C_{L} needs to be charged to the high voltage level V_{DD} again, the switch 110 connects the load capacitor C_{L} and the storage capacitor C_{S} to enable the equalization of them firstly, and at this moment, the storage capacitor C_{S} at higher voltage level charges the load capacitor C_{L}. After the equalization is completed, the switch 110 switches to connect the output side V_{OUT} and the capacitive load 200 to enable the output side V_{OUT} to charge the capacitive load 200.

Thus, the output side V_{OUT} needn't charge or discharge the load capacitor C_{L} to the total range of the voltage level; therefore, pushing the load capacitor C_{L} to the voltage level required by the load does not need too much current (The extra current consumption is used in the switching actions of the switch 110). Thus, a portion of drive current can be saved, the current consumed by loads can be reduced, and the objective of saving power can be achieved.

Based on the abovementioned charge/discharge process, the voltages of the nodes in the circuit of the present invention are deduced as follows:

Let C_{S}=X·C_{L}, and thus, X is the ratio of the capacitance of the storage capacitor C_{S} to the capacitance of the load capacitor C_{L}. The initial state is that the load capacitor C_{L} is coupled to the output side V_{OUT} and is charged to the high voltage level V_{DD}, the storage capacitor C_{S} is in floating state without any charge thereinside.

Step 0.1

V_{OUT}=V_{DD}=N_{L} (The load capacitor C_{L} is charged via the transistor PM);
N_{S}=0 (The storage capacitor C_{S} is in floating state);
   Step 0.2
The load capacitor C_{L} shares charges with the storage capacitor C_{S} via the switch 110; therefore, the voltage of Node N_{S} between the storage capacitor Cₛ and the switch 110, and the voltage of Node N_{L} between the load capacitor C_{L} and the switch 110 are:
N_{S}=N_{L}=(C_{L}·V_{DD})/(C_{L}+XC_{L})=V_{DD}/(1+X); Step 0.3
V_{OUT}=N_{L}=V_{SS} (The load capacitor C_{L} discharges via the transistor NM);
N_{S}=V_{DD}/(1+X);
   Step 0.4
The storage capacitor C_{S} shares charges with the load capacitor C_{L} via the switch 110; therefore,
N_{S}=N_{L}=((V_{DD}/(1+X))·XC_{L})/(C_{L}+XC_{L})=XV_{DD}/(1+X)²;
   Step 1.1
V_{OUT}=V_{DD}=N_{L};
N_{S}=XV_{DD}/(1+X)²;
Step 1.2

$$\begin{matrix}{N}_{S} = {N}_{L} \\ = ( {C}_{L} \cdot {V}_{DD} + ( {XV}_{DD} / {( 1 + X )}^{2} ) \cdot {XC}_{L} ) / ( {C}_{L} + {XC}_{L} ) \\ = ( {X}^{2} + {( 1 + X )}^{2} ) {V}_{DD} / {( 1 + X )}^{3} ;\end{matrix}$$

Step 1.3
V_{OUT}=N_{L}=V_{SS};
N_{S}=(X²+(1+X)²) V_{DD}/(1+X)³;
Step 1.4

$$\begin{matrix}{N}_{S} = {N}_{L} \\ = ( ( ( {( 1 + X )}^{2} + {X}^{2} ) {V}_{DD} / {( 1 + X )}^{3} ) \cdot {XC}_{L} ) / ( {C}_{L} + {XC}_{L} ) \\ = ( {X}^{3} + {X ( 1 + X )}^{2} ) {V}_{DD} / {( 1 + X )}^{4}\end{matrix}$$

Steps n.1˜n.4 can be deduced from the abovementioned Steps 0.1˜0.4 and Steps 1.1˜1.4, and after n time iterations of the process that the load capacitor C_{L} at the high voltage level V_{DD} shares charges with the storage capacitor C_{S}, the voltage of Node N_{S} can be expressed as:

$$\begin{matrix}{N}_{S , H} = ( {( 1 + X )}^{2 n} / {( 1 + X )}^{2 n + 1} ) Σ ( ( {X}^{2 i} / {( 1 + X )}^{2 i} ) \cdot {V}_{DD} ) \\ = ( 1 / ( 1 + X ) ) Σ ( ( {X}^{2 i} / {( 1 + X )}^{2 i} ) \cdot {V}_{DD} ) , whierin i = 0 \sim n .\end{matrix}$$

$$\begin{matrix}When n \to ∞ , lim {N}_{S , H} = ( 1 / ( 1 + X ) ) lim Σ ( ( {X}^{2 i} / {( 1 + X )}^{2 i} ) \cdot {V}_{DD} ) \\ = ( 1 / ( 1 + X ) ) \cdot ( ( 1 / 1 - ( {X}^{2} / {( 1 + X )}^{2} ) ) \cdot {V}_{DD} ) \\ = ( 1 / ( 1 + X ) ) \cdot ( ( 1 / ( ( 2 X + 1 ) / {( 1 + X )}^{2} ) ) \cdot {V}_{DD} ) \\ = ( ( X + 1 ) / ( 2 X + 1 ) ) \cdot {V}_{DD} .\end{matrix}$$

Similarly, after n time iterations of the process that the load capacitor C_{L} at the low voltage level V_{SS} shares charges with the storage capacitor C_{S}, the voltage of_{Node N}_{S} can be expressed as:

$$\begin{matrix}{N}_{S , L} = ( {X ( 1 + X )}^{2 n} / {( 1 + X )}^{2 n + 2} ) Σ ( ( {X}^{2 i} / {( 1 + X )}^{2 i} ) \cdot {V}_{DD} ) \\ = ( X / ( 1 + X ) ) Σ ( ( {X}^{2 i} / {( 1 + X )}^{2 i} ) \cdot {V}_{DD} ) , wherein i = 0 \sim n .\end{matrix}$$

$$\begin{matrix}When n \to ∞ , lim {N}_{S , L} = ( X / ( 1 + X ) ) lim Σ ( ( {X}^{2 i} / {( 1 + X )}^{2 i} ) \cdot {V}_{DD} ) \\ = ( X / ( 1 + X ) ) \cdot ( ( 1 / ( 1 - ( {X}^{2} / {( 1 + X )}^{2} ) ) \cdot {V}_{DD} ) \\ = ( X / ( 1 + X ) ) \cdot ( ( 1 / ( ( 2 X + 1 ) / {( 1 + X )}^{2} ) ) \cdot {V}_{DD} ) \\ = ( X / 2 X + ) ) \cdot {V}_{DD} .\end{matrix}$$

When the capacitance of the storage capacitor C_{S} is equal to the capacitance of the load capacitor C_{L}, i.e. X=1, and when the operation of the capacitive load 200 has been stabilized,
N_{S, H}=((1+1)/(2×1+1))·V_{DD}=⅔V_{DD}, and N_{S, L}=((1)/(2×1+1))·V_{DD}=⅓V_{DD}. The voltages of Node N_{S} and Node N_{L} of this case are shown in FIG. 4. In Step n.1, the output side V_{OUT} connects with the capacitive load 200 and charges the capacitive load 200, i.e. charges the load capacitor C_{L}; as the load capacitor C_{L} has been pre-charged to ⅓V_{DD} initially (It is assumed that the low voltage level V_{SS}=0), the voltage of Node N_{L} is raised to the high voltage level V_{DD} from ⅓V_{DD}, and at this stage, the voltage of Node N_{S} maintains ⅓V_{DD}.

After the charging procedure is completed, the process enters into Step n.2, and the load capacitor C_{L} undertakes a discharging procedure. At this stage, the load capacitor C_{L} equalizes the storage capacitor C_{S}, and the voltage of Node N_{S} is raised from ⅓V_{DD} to ⅔V_{DD}, and the voltage of Node N_{L} is decreased from V_{DD} to ⅔V_{DD}.

After the equalization is completed, the process enters into Step n.3, and the load capacitor C_{L} discharges completely. At this stage, the voltage of Node N_{L} is decreased from ⅔V_{DD} to V_{SS}, and the voltage of Node N_{S} maintains ⅔V_{DD}.

Then, before the load capacitor C_{L} is charged again, the process enters into Step n.4. At this stage, the storage capacitor C_{S} equalizes the load capacitor C_{L}, and the voltage of Node N_{S} is decreased from ⅔V_{DD} to ⅓V_{DD}, and the voltage of Node N_{L} is raised from V_{SS} to ⅓V_{DD}. After Step n.4, the process returns to Step n.1 to repeat the same process.

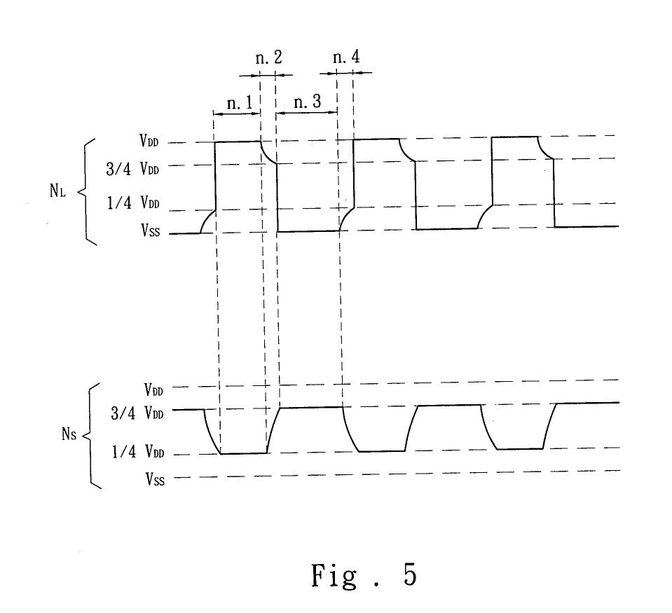

Similarly, When the ratio of the capacitance of the storage capacitor C_{S} to the capacitance of the load capacitor C_{L} is ½, i.e. X=½, and when the operation of the capacitive load 200 has been stabilized, N_{S,H}=((1+½)/(2×(½)+1))·V_{DD}=¾V_{DD}, and N_{S,L}=((½)/(2×(½)+1))·V_{DD}=¼V_{DD}. The voltages of Node N_{S} and Node N_{L} of this case are shown in FIG. 5.

In summary, the power-saving ratio of the present invention is: R=X/(2X+1), wherein R is the ratio of how much power is saved, and X is the ratio of the capacitance of the storage capacitor C_{S} to the capacitance of the load capacitor C_{L}. Therefore, R=⅓ when the capacitance of the storage capacitor C_{S} is equal to the capacitance of the load capacitor C_{L}. For example, the capacitance of the load capacitor C_{L} is 20 pf, and the built-in capacitance is also 20 pf, and then, X=20 pf/20 pf=1, and R=⅓. Thus, in the present invention, when the capacitance of the storage capacitor C_{S} is equal to the capacitance of the load capacitor C_{L}, 33% power can be saved. Further, R=¼when the ratio of the capacitance of the storage capacitor C_{S} to the capacitance of the load capacitor C_{L} is ½. For example, the capacitance of the load capacitor C_{L} is 20 pf, and the built-in capacitance is 10 pf, and then, X=10 pf/20 pf=½, and R=¼. Thus, in the present invention, when the capacitance of the storage capacitor C_{S} is equal to half the capacitance of the load capacitor C_{L}, 25% power can be saved.

When the capacitance of the storage capacitor C_{S} is extremely greater than the capacitance of the load capacitor C_{L}, i.e. X is infinitely great, R=½. Therefore, the theoretical maximum power-saving effect of the present invention is 50%.

The spirit of the present invention is: a storage capacitor C_{S} is installed between a capacitive load and the output side V_{OUT} of a drive element, and the storage capacitor C_{S} and the load capacitor C_{L} of the capacitive load are equalized beforehand, and then the output side V_{OUT} charges or discharges the load capacitor C_{L} with the load capacitor C_{L} having been at an initial voltage level. Thus, the output side V_{OUT} needn't charge or discharge to the total range of the voltage level. Therefore, a portion of drive current can be saved, the current consumed by loads can be reduced, and then the objective of saving power can be achieved.

Those described above are only the preferred embodiments of the present invention, and it is not intended to limit the scope of the present invention, and any equivalent modification and variation according to the spirit of the present invention is to be also included within the scope of the claims of the present invention.

What is claimed is:

1. A structure for reducing the current consumption of a capacitive load, which transfers voltage signals from the output side of a drive element to a capacitive load, comprising:
a storage capacitor, installed between said output side and said capacitive load; and
a switch, switching the connection between said storage capacitor and said capacitive load and the connection between said output side and said capacitive load.

2. A method for reducing the current consumption of a capacitive load, applying to the structure comprising: a storage capacitor, installed between a output side of a drive element and said capacitive load; and a switch, switching the connection between said storage capacitor and said capacitive load and the connection between said output side and said capacitive load; and comprising the following steps:
said switch connecting said storage capacitor and said capacitive load to perform an equalization procedure and equalize the capacitance of said storage capacitor and the capacitance of a load capacitor of said capacitive load when said output side is to undertake a voltage signal transition; and
said switch switching to connect said output side and said capacitive load to enable said output side to charge or discharge said capacitive load after said equalization procedure is completed.
